(19) United States
(12) Patent Application Publication
(10) Pub. No.: US 2013/0126820 A1
(43) Pub. Date: May 23, 2013

(54) VARIABLE AND REVERSIBLE RESISTIVE MEMORY STORAGE ELEMENT AND MEMORY STORAGE MODULE HAVING THE SAME

(71) Applicants: Chrong-Jung Lin, Hsinchu City (TW); Ya-Chin King, Taipei City (TW)

(72) Inventors: Chrong-Jung Lin, Hsinchu City (TW); Ya-Chin King, Taipei City (TW)

(21) Appl. No.: 13/674,519

(22) Filed: Nov. 12, 2012

(30) Foreign Application Priority Data
Nov. 18, 2011 (TW) 100142395

(51) Int. Cl. H01L 45/00

(52) U.S. Cl. CPC H01L 45/00
USPC 257/4

(57) ABSTRACT

A variable and reversible resistive memory storage element and a memory storage module having the same are provided. The memory storage module comprises a select gate element and the resistive memory storage element. The select gate element comprises two source/drain regions. The resistive memory storage module comprises a first electrode, a first high-k dielectric layer and a second electrode. The first electrode is a semiconductor doping area, which is one of the two source/drain regions of the select gate element. The first high-k dielectric layer is formed on the first electrode to provide a variable resistance. The second electrode is a first metal gate formed on the first high-k dielectric layer.

### RELATED APPLICATIONS

This application claims priority to Taiwan Application Serial Number 100142395, filed Nov. 18, 2011, which is herein incorporated by reference.

### BACKGROUND

1. Technical Field

The present disclosure relates to a memory storage unit. More particularly, the present disclosure relates to a variable and reversible resistive memory storage element and a memory storage module having the same.

2. Description of Related Art

The development of semiconductor memory devices having higher integration and lower power consumption has been the focus of recent research.

Non-volatile memory, nonvolatile memory, NVM or non-volatile storage, is computer memory that can retain the stored information even when not powered. Examples of non-volatile memory include read-only memory, flash memory, most types of magnetic computer storage devices (e.g. hard disks, floppy disk drives, and magnetic tape), optical disc drives, and early computer storage methods such as paper tape and punch cards.

Urgent demands on finding new solutions for next generation NVM have spurred many research activities in ReRAM (resistance-change random-access memory) studies. The promising results shown in recent ReRAM works suggest that it might be able to substitute floating gate memories and become the next mainstream NVM device. The switching resistor in the 1T+1R ReRAM cell (one transistor+1 Resistor) is realized by backend process with a metal-dielectric-metal structure.

### SUMMARY

An aspect of the present disclosure is to provide a variable and reversible resistive memory storage element. The resistive memory storage element comprises a first electrode, a high-k dielectric layer and a second electrode. The first electrode is a semiconductor doping area. The high-k dielectric layer is formed on the first electrode to provide a variable resistance. The second electrode is a metal gate formed on the high-k dielectric layer.

Another aspect of the present disclosure is to provide a memory storage module. The memory storage module comprises a select gate element and the resistive memory storage element. The select gate element comprises two source/drain regions. The resistive memory storage module comprises a first electrode, a first high-k dielectric layer and a second electrode. The first electrode is a semiconductor doping area, which is one of the two source/drain regions of the select gate element. The first high-k dielectric layer is formed on the first electrode to provide a variable resistance. The second electrode is a first metal gate formed on the first high-k dielectric layer.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1A is a diagram of a resistive memory storage element in an embodiment of the present disclosure;

FIG. 1B is a diagram of a resistive memory storage element in another embodiment of the present disclosure;

FIG. 2A is a diagram depicting the equivalent circuit of the resistive memory storage element depicted in FIG. 1A;

FIG. 2B is a diagram depicting the equivalent circuit of the resistive memory storage element depicted in FIG. 3;

FIG. 3 is a diagram of a memory storage module in an embodiment of the present disclosure;

FIG. 4 is a diagram depicting the characteristic of the current and voltage of the resistive memory storage element in an embodiment of the present disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

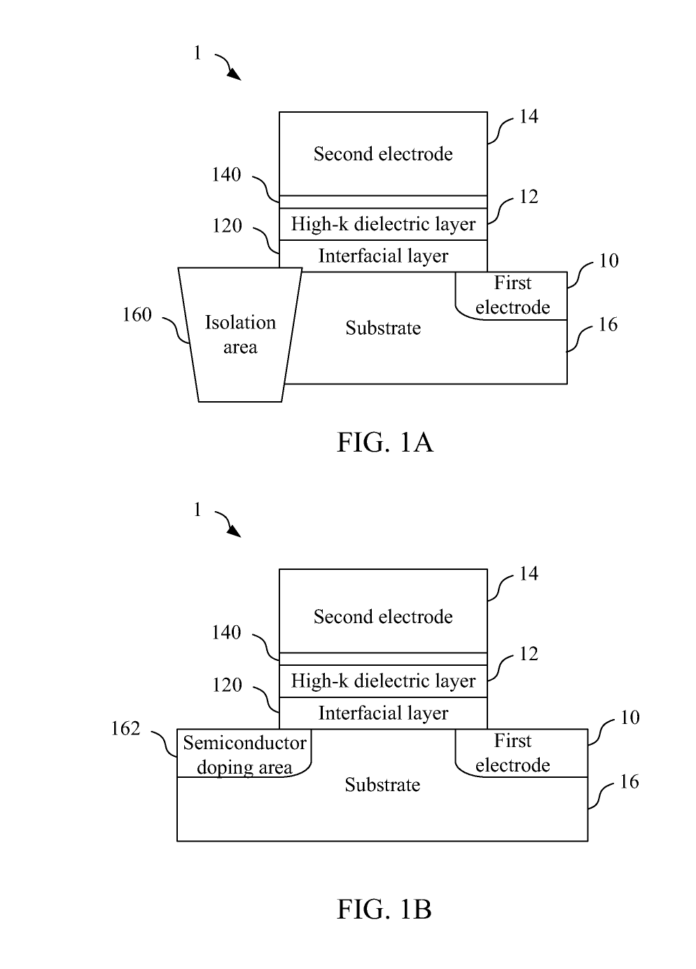

FIG. 1A is a diagram of a resistive memory storage element 1 in an embodiment of the present disclosure. The resistive memory storage element 1 has a variable and reversible resistance. The resistive memory storage element 1 comprises a first electrode 10, a high-k dielectric layer 12 and a second electrode 14.

The first electrode 10 is a semiconductor doping area. In an embodiment, the resistive memory storage element 1 comprises a substrate 16. In different embodiments, the substrate 16 can be a Si substrate, a silicon-on-insulator (SOI) substrate or a silicon-on-sapphire (SOS) substrate. The first electrode 10, i.e. the semiconductor doping area, is formed in the substrate 16. In the present embodiment, the substrate 16 further comprises an isolation area 160. The high-k dielectric layer 12 is formed above the isolation area 160 and the semiconductor doping area of the substrate 16 and contacts thereon. In another embodiment, the structure of the substrate 16 further comprises another semiconductor doping area 162 as shown in FIG. 1B. The high-k dielectric layer 12 can thus be formed above the semiconductor doping area 162 and the first electrode 10 and contact thereon.

In an embodiment, the high-k dielectric layer 12 is a metal oxide layer having a high dielectric constant and comprises the material of HfO₂, SrO₂ or their combination. In other embodiment, the high-k dielectric layer 12 may comprise other material having a high dielectric constant. It is noted that the term “high-k” means that the dielectric constant of the high-k dielectric layer 12 is larger than the dielectric constant of the material of SiO₂ or SiOxNy. The material of SiO₂ or SiOxNy is the common material for forming the gate dielectric layer. However, as the size of the semiconductor element becomes smaller due to the advancement of the manufacturing process, the thickness of the dielectric layer made of SiO₂ decreases as well. The decreasing thickness of the dielectric layer results in larger leakage current such that the efficiency of the element degrades. The semiconductor element formed by using the high-k material such as HfO₂, SrO₂ or their combination has lower leakage current than the semiconductor element formed by using the material of SiO₂ when they have the same equivalent oxide thickness (EOT). Therefore, it is preferable to replace the conventional thin film made by SiO₂ or SiOxNy by thicker layer made by high-k material such that the electrical property of the semiconductor element described above can be satisfied.

In the present embodiment, in order to have a better electrical connection between the high-k dielectric layer 12 and the substrate 16 and the first electrode 10, an interfacial layer 120 can be formed between the high-k dielectric layer 12 and the substrate 16 and the first electrode 10 as shown in FIG. 1A. The interfacial layer 120 has a dielectric constant smaller than that of the high-k dielectric layer 12, wherein the interfacial layer 120 comprises the material of SiO₂, SiOxNy or their combination. In other embodiments, the interfacial layer 120 may comprise other suitable material.

The second electrode 14 is a metal gate formed on the high-k dielectric layer 12. Comparing to Poly-Si, the metal gate can possess a better thermal stability, a retardation of the Fermi-level pinning effect and a lower resistance. Further, the metal gate can operate well under high frequency condition. The basic requirements for a novel metal gate technology include providing suitable work function values at the gate dielectric interface, the good enough thermal stability with the underlying gate dielectrics and a compatible device integration process. In order to meet the requirements described above, the second electrode 14 can comprise the material of Cu, Al, Cu—Al alloys, Ti or their combination. In an embodiment, the resistive memory storage element 1 further comprises a barrier layer 140 to separate the high-k dielectric layer 12 and the second electrode 14, wherein the barrier layer 140 comprises the material of TiN, TaN or their combination.

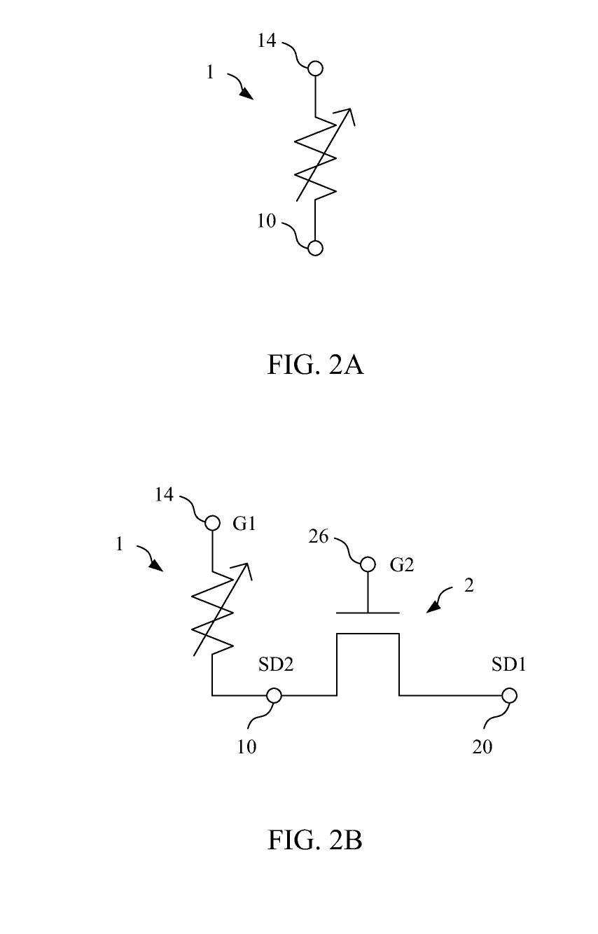

FIG. 2A is a diagram of the equivalent circuit of the resistive memory storage element 1 depicted in FIG. 1A. The equivalent circuit of the resistive memory storage element 1 is a variable and reversible resistor as shown in FIG. 2A. The fabrication of the structure of the resistive memory storage element 1 described in the above embodiments can be integrated into the conventional manufacturing process without additional mask or additional memory manufacturing steps. Further, the thermal cycle process needs not to be changed as well. The cost and the area can thus be saved.

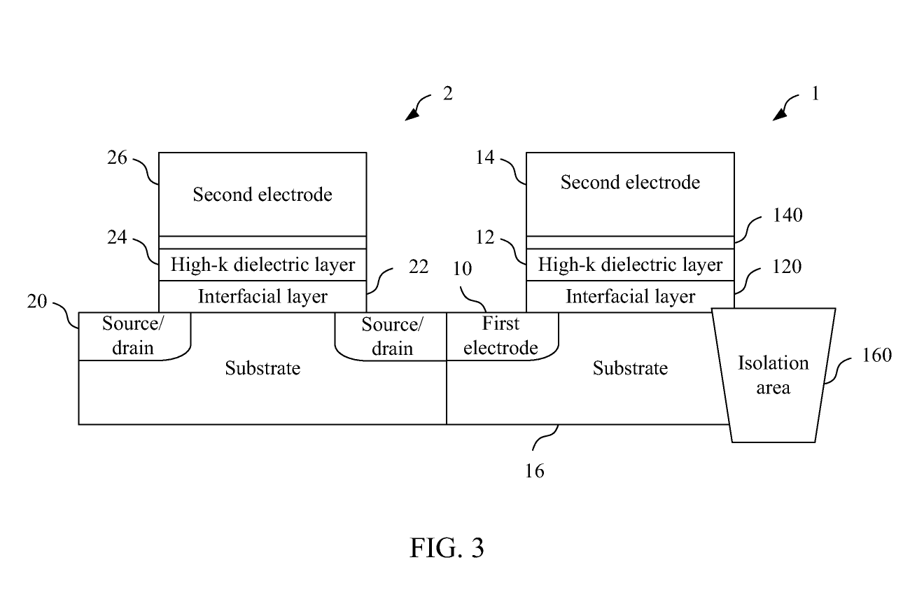

FIG. 3 is a diagram of a memory storage module 3 in an embodiment of the present disclosure. The memory storage module 3 comprises the resistive memory storage element 1 depicted in FIG. 1A and a select gate element 2.

The structure of the select gate element 2 is similar to the resistive memory storage element 1. The select gate element 2 comprises two source/drain regions 20, an interfacial layer 22, a high-k dielectric layer 24 and a metal gate 26. In the present embodiment, the first electrode 10 of the resistive memory storage element 1 is substantially one of the two source/drain regions 20 of the select gate element 2. Consequently, the equivalent circuit of the memory storage module 3 having the memory storage element 1 and the select gate element 2 comprises a variable resistor and a transistor connected in series as shown in FIG. 2B.

In an embodiment, by applying a gate voltage on the second electrode 14 for a specific time period, a forming process of the resistive memory storage element 1 can be performed. For example, by applying and maintaining a gate voltage of 4V on the second electrode 14 for 100 us to 100 s, the forming process can be performed such that the resistive memory storage element 1 turns from an initial high resistance state to a low resistance state. In other embodiments, different time periods or different levels of the gate voltage can be adapted to perform the forming process according to the variation of the structure of the resistive memory storage element 1.

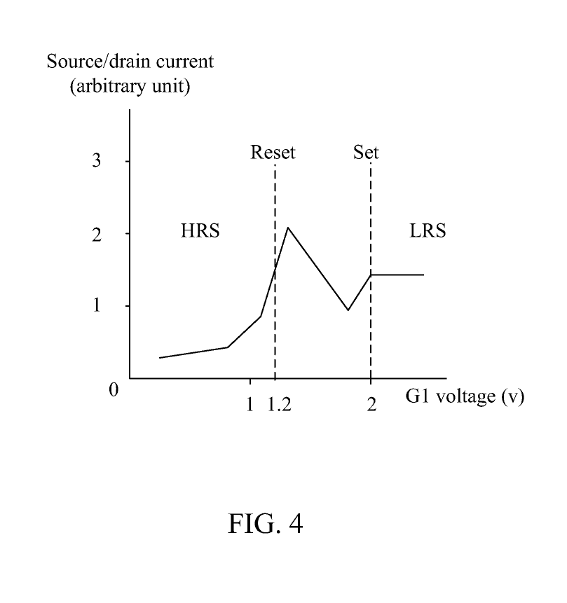

FIG. 4 is a diagram depicting the characteristic of the current and voltage of the resistive memory storage element 1 in an embodiment of the present disclosure. In an embodiment, after applying a gate voltage (e.g. 2.5 V) on G2 end in FIG. 2B, i.e. the metal gate 26 of the select gate element 2, the operation of the resistive memory storage element 1 can be controlled by applying a gate voltage on G1 end depicted in FIG. 2B, i.e. the gate of the resistive memory storage element 1. For example, when a voltage level of 0 V is maintained at SD1 end (the source/drain region of the select gate element 2) depicted in FIG. 2, the SD2 end is maintained at 0 V as well. Under such a condition, a procedure called ‘set’ can be performed by applying a gate voltage of 2 V to G1 end to turn the resistive memory storage element 1 to a low resistance state (LRS) if the initial sate of the resistive memory storage element 1 is in a high resistance state (HRS). On the other hand, if the initial sate of the resistive memory storage element 1 is in low high resistance state, a procedure called ‘reset’ can be performed by applying a gate voltage of 1.2 V to G1 end to turn the resistive memory storage element 1 to the high resistance state. When the resistive memory storage element 1 is in the high resistance state, the source/drain current is lower than the source/drain current generated when the resistive memory storage element 1 is in the low resistance state. Hence, by controlling the gate voltage applied to the resistive memory storage element 1, the state of the resistance can be modified to accomplish the data storing mechanism.

Accordingly, the fabrication of the structure of the resistive memory storage element 1 described of the present disclosure can be integrated into the conventional manufacturing process without additional mask or additional memory manufacturing steps. Further, the thermal cycle process needs not to be changed as well. The cost and the area can thus be saved.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A variable and reversible resistive memory storage element comprising:
a first electrode that is a semiconductor doping area;
a high-k dielectric layer formed on the first electrode to provide a variable resistance; and
a second electrode that is a metal gate formed on the high-k dielectric layer.

2. The resistive memory storage element of claim 1, wherein the high-k dielectric layer is a metal-oxide layer and comprises the material of HfO₂, SrO₂ or their combination.

3. The resistive memory storage element of claim 1, further comprising an interfacial layer having a dielectric constant smaller than that of the high-k dielectric layer.

4. The resistive memory storage element of claim 3, wherein the interfacial layer comprises the material of SiO₂, SiOxNy or their combination.

5. The resistive memory storage element of claim 1, further comprising a barrier layer between the high-k dielectric layer and the second electrode.

6. The resistive memory storage element of claim 5, wherein the barrier layer comprises the material of TiN, TaN or their combination.

7. The resistive memory storage element of claim 1, wherein the second electrode comprises the material of Cu, Al, Cu—Al alloys, Ti or their combination.

8. The resistive memory storage element of claim 1, wherein a forming process is performed by applying a gate voltage on the second electrode for a specific time period.

9. The resistive memory storage element of claim 1, further comprising a substrate, wherein the semiconductor doping area is formed in the substrate and the high-k dielectric layer contacts the substrate and the semiconductor doping area.

10. The resistive memory storage element of claim 9, wherein the substrate is a Si substrate, a silicon-on-insulator (SOI) substrate or a silicon-on-sapphire (SOS) substrate.

11. A memory storage module comprising:
a select gate element comprising two source/drain regions; and
a resistive memory storage element comprising:
a first electrode that is a semiconductor doping area and is one of the two source/drain regions of the select gate element;
a first high-k dielectric layer formed on the first electrode to provide a variable resistance; and
a second electrode that is a first metal gate formed on the first high-k dielectric layer.

12. The memory storage module of claim 11, wherein the select gate element further comprises:
a second high-k dielectric layer formed on the two source/drain regions; and
a second metal gate formed on the second high-k dielectric layer.

13. The memory storage module of claim 11, wherein the first high-k dielectric layer is a metal-oxide layer and comprises the material of HfO₂, SrO₂ or their combination.

14. The memory storage module of claim 11, further comprising an interfacial layer having a dielectric constant smaller than that of the first high-k dielectric layer.

15. The memory storage module of claim 14, wherein the interfacial layer comprises the material of SiO₂, SiON or their combination.

16. The memory storage module of claim 11, further comprising a barrier layer between the first high-k dielectric layer and the second electrode.

17. The memory storage module of claim 16, wherein the barrier layer comprises the material of TiN, TaN or their combination.

18. The memory storage module of claim 11, wherein the second electrode comprises the material of Cu, Al, Cu—Al alloys, Ti or their combination.

19. The memory storage module of claim 11, wherein a forming process is performed by applying a gate voltage on the second electrode for a specific time period.

20. The memory storage module of claim 11, further comprising a substrate, wherein the two source/drain regions are formed in the substrate and the first high-k dielectric layer contacts the substrate and one of the two source/drain regions.

21. The memory storage module of claim 20, wherein the substrate is a Si substrate, a silicon-on-insulator (SOI) substrate or a silicon-on-sapphire (SOS) substrate.
